(19) United States
(12) Patent Application Publication
(10) Pub. No.: US 2017/0030957 A1
(43) Pub. Date: Feb. 2, 2017

(54) PARTIAL DISCHARGE DETECTION RELAY MATRIX FOR MULTIPLE LEAD ANALYSIS

(71) Applicant: Adam James Bierman, Fort Collins, CO (US)

(72) Inventor: Adam James Bierman, Fort Collins, CO (US)

(73) Assignee: AKTIEBOLAGET SKF, GOTEBORG (SE)

(21) Appl. No.: 14/814,621

(22) Filed: Jul. 31, 2015

(51) Int. Cl. G01R 31/02; G01R 31/14

(52) U.S. Cl. CPC G01R 31/024; G01R 31/14

(57) ABSTRACT

A system and method for detecting a partial discharge in a device. The system includes an impulse discharge board, and a relay matrix. The relay matrix includes a first relay connected to the impulse discharge board, and a second relay connected to the first relay, a first phase of the device, and a ground connection of the relay matrix. A first electrical pulse from the impulse discharge board passes through the first relay and the second relay to the first phase of the device when the second relay is in a first position. The first phase of the device is connected to the ground connection when the second relay is in a second position. The system further includes a partial discharge detection board connected to the impulse discharge board, the first relay, or both. The partial discharge detection board measures reflected electrical pulses from the device.

### BACKGROUND

Partial discharge refers to a localized dielectric breakdown in a portion of the electrical insulation system of a device (e.g., a motor) when the insulation system is under high voltage stress. The breakdown is caused by one or more cracks, voids, or inclusions in the insulation system. Partial discharges cause small, but significant, damages to the device, and indicate that the insulation system is beginning to fail, which may lead to catastrophic damage in the future. As such, it is desirable to detect partial discharges so that the insulation system may be repaired or replaced before such damage occurs.

### SUMMARY

Embodiments of the disclosure may provide a system for detecting a partial discharge. The system includes an impulse discharge board, and a relay matrix. The relay matrix includes a first relay connected to the impulse discharge board, and a second relay connected to the first relay, a first phase of the device, and a ground connection of the relay matrix. A first electrical pulse from the impulse discharge board passes through the first relay and the second relay to the first phase of the device when the second relay is in a first position. The first phase of the device is connected to the ground connection when the second relay is in a second position. The system further includes a partial discharge detection board connected to the impulse discharge board, the first relay, or both. The partial discharge detection board measures reflected electrical pulses from the device.

Embodiments of the disclosure may also provide a relay matrix including a first relay. The first relay includes a first connector configured to be connected to a first voltage supply, a second connector configured to be connected to a second voltage supply, a third connector, and a switch configured to connect the first and third connectors of the first relay when the switch is in a first position and to connect the second and third connectors of the first relay when the switch is in a second position. The relay matrix further includes a second relay. The second relay includes a first connector connected to the third connector of the first relay, a second connector connected to a ground, a third connector configured to be coupled to a first phase of a device, and a switch configured to connect the first and third connectors of the second relay when the switch is in a first position and to connect the second and third connectors of the second relay when the switch is in a second position.

Embodiments of the disclosure may further provide a method for detecting a partial discharge in a device. The method includes actuating a relay matrix to connect an impulse discharge board to a first phase of a device, and transmitting a first electrical pulse from the impulse discharge board, through the relay matrix, to the first phase of the device. The first electrical pulse reflects off of the device producing a first reflected electrical pulse. The method may also include measuring the first reflected electrical pulse with a detection board, and actuating the relay matrix to connect the impulse discharge board to a second phase of the device.

### BRIEF DESCRIPTION OF THE DRAWINGS

The accompanying drawings, which are incorporated in and constitute a part of this specification, illustrate an embodiment of the present teachings and together with the description, serve to explain the principles of the present teachings. In the figures:

FIG. 1 illustrates a schematic view of a system for detecting a partial discharge, according to an embodiment.

FIG. 2 illustrates a flow chart of a method for detecting a partial discharge, according to an embodiment.

It should be noted that some details of the figures have been simplified and are drawn to facilitate understanding of the embodiments rather than to maintain strict structural accuracy, detail, and scale.

### DETAILED DESCRIPTION

Reference will now be made in detail to embodiments of the present teaching, examples of which are illustrated in the accompanying drawing. In the drawings, like reference numerals have been used throughout to designate identical elements, where convenient. In the following description, reference is made to the accompanying drawings that form a part of the description, and, in which is shown by way of illustration, one or more specific example embodiments in which the present teachings may be practiced.

Further, notwithstanding that the numerical ranges and parameters setting forth the broad scope of the disclosure are approximations; the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein.

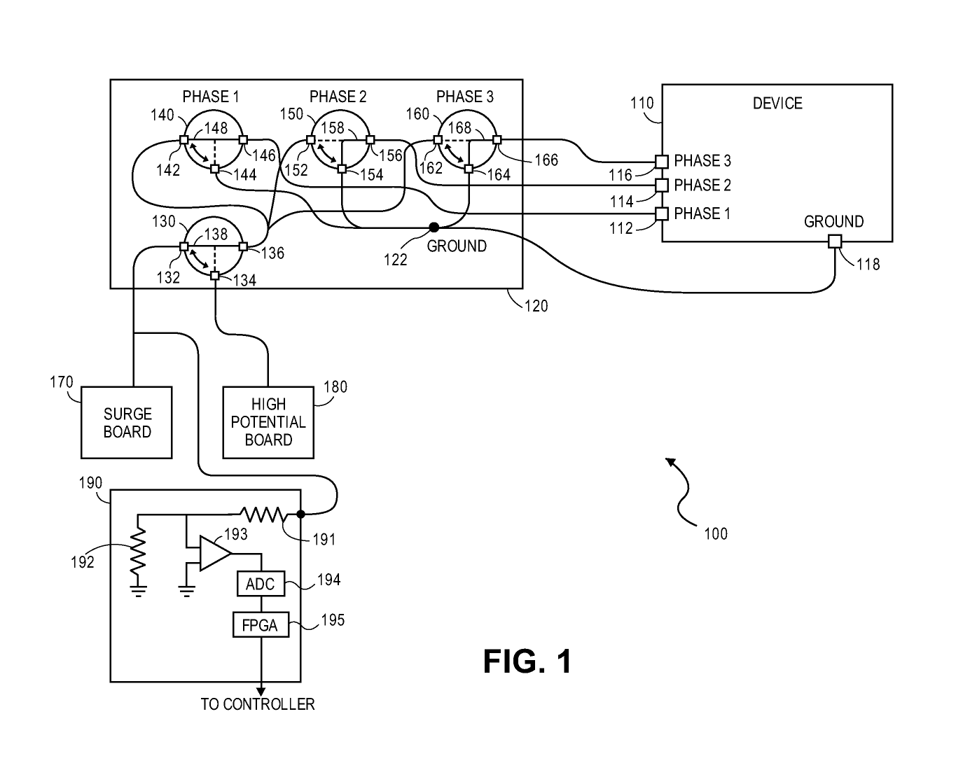

FIG. 1 illustrates a schematic view of a system 100 for detecting a partial discharge, according to an embodiment. The system 100 includes a device 110 that is to be tested. More particularly, the device 110 includes electrical insulation that is to be tested for partial discharges. The device 110 includes a motor completely assembled with a rotor in place, a stator that has had the rotor removed for preventative maintenance, a new motor being quality tested, a single-form wound coil designed for high voltage stresses, DC Interpoles, or any combination of the prior. The device 110 includes three conductors 112, 114, 116. Each conductor 112, 114, 116 corresponds to a different electrical phase, and the phases are offset from one another by 120 degrees. The device 110 also includes a ground connection 118.

The system 100 also includes a relay matrix 120 that is connected to the device 110. The relay matrix 120 includes one or more relays (four are shown: 130, 140, 150, 160). The first relay 130 includes a first connection 132 that is connected to an impulse discharge board 170. The impulse discharge board 170 is configured to supply high voltage pulses to the first relay 130. The pulses have a voltage from 0V to 15 kV and a duration of less than one hundred nanoseconds, while the reflections last up to several hundred microseconds depending on the characteristics of the coil.

The first relay 130 also includes a second connection 134 that is connected to a high potential (also known as “HIPOT”) board 180. The high potential board 180 is configured to supply a high voltage with a longer duration to the first relay 130, for example, at low current, with tests lasting up to about 20 minutes. The high voltage is from about 0V to 15 kV depending on the device model and has a duration of less than one hundred nanoseconds and a reflection lasting up to several hundred microseconds.

The first relay 130 also includes a third connection 136 that is connected to the second relay 140, the third relay 150, and the fourth relay 160. The first relay 130 further includes a switch 138 that is actuated between first and second positions. In the first position, the switch 138 connects the first and third connections 132, 136. Thus, when the switch 138 is in the first position, the impulse discharge board 170 is connected to the second, third, and fourth relays 140, 150, 160. In addition, when the switch 138 is in the first position, the high potential board 180 is disconnected from the impulse discharge board 170 and from the second, third, and fourth relays 140, 150, 160.

When the switch 138 is in the second position, the switch 138 connects the second and third connections 134, 136. Thus, when the switch 138 is in the second position, the high potential board 180 is connected to the second, third, and fourth relays 140, 150, 160. In addition, when the switch 138 is in the second position, the impulse discharge board 170 is disconnected from the high potential board 180 and from the second, third, and fourth relays 140, 150, 160.

The second relay 140 includes a first connection 142 that is connected to the first relay 130. More particularly, the first connection 142 of the second relay 140 is connected to the third connection 136 of the first relay 130. The second relay 140 also includes a second connection 144 that is connected to a ground connection 122 in the relay matrix 120. The second relay 140 also includes a third connection 146 that is connected to the first connection 112 (e.g., the first phase) of the device 110.

The second relay 140 further includes a switch 148 that is actuated between first and second positions. In the first position, the switch 148 connects the first and third connections 142, 146. Thus, when the switch 148 is in the first position, the first relay 130 is connected to the device 110. When the switch 148 is in the second position, the switch 148 connects the second and third connections 144, 146. Thus, when the switch 148 is in the second position, the first connection 114 of the device 110 is connected to the ground connection 122 of the relay matrix 120.

The third relay 150 includes a first connection 152 that is connected to the first relay 130. More particularly, the first connection 152 of the third relay 150 is connected to the third connection 136 of the first relay 130. The third relay 150 also includes a second connection 154 that is connected to the ground connection 122 in the relay matrix 120. The third relay 150 also includes a third connection 156 that is connected to the second connection 114 (e.g., the second phase) of the device 110.

The third relay 150 further includes a switch 158 that is actuated between first and second positions. In the first position, the switch 158 connects the first and third connections 152, 156. Thus, when the switch 158 is in the first position, the first relay 130 is connected to the device 110. When the switch 158 is in the second position, the switch 158 connects the second and third connections 154, 156. Thus, when the switch 158 is in the second position, the second connection 114 of the device 110 is connected to the ground connection 122 of the relay matrix 120.

The fourth relay 160 includes a first connection 162 that is connected to the first relay 130. More particularly, the first connection 162 of the fourth relay 160 is connected to the third connection 136 of the first relay 130. The fourth relay 160 also includes a second connection 164 that is connected to the ground connection 122 in the relay matrix 120. The fourth relay 160 also includes a third connection 166 that is connected to the third connection 116 (e.g., the third phase) of the device 110.

The fourth relay 160 further includes a switch 168 that is actuated between first and second positions. In the first position, the switch 168 connects the first and third connections 162, 166. Thus, when the switch 168 is in the first position, the first relay 130 is connected to the device 110. When the switch 168 is in the second position, the switch 168 connects the second and third connections 164, 166. Thus, when the switch 168 is in the second position, the third connection 116 of the device 110 is connected to the ground connection 122 of the relay matrix 120.

The system 100 also includes a partial discharge detection board 190. The partial discharge detection board 190 is connected to the impulse discharge board 170, the (first connection 132 of the) first relay 130, or both. The partial discharge detection board 190 includes one or more resistors (two are shown: 191, 192). The resistors 191, 192 form a voltage divider. The partial discharge detection board 190 also includes one or more operational amplifiers (one is shown: 193), one or more analog-to-digital converters (one is shown: 194), one or more field programmable gate arrays (one is shown: 195), and a bus 196 (e.g., an 8 bit bus) to a microcontroller. As described in more detail below, the partial discharge detection board 190 is able to receive and measure reflections from the device 110 when the device 110 is exposed to electrical pulses from the impulse discharge board 170.

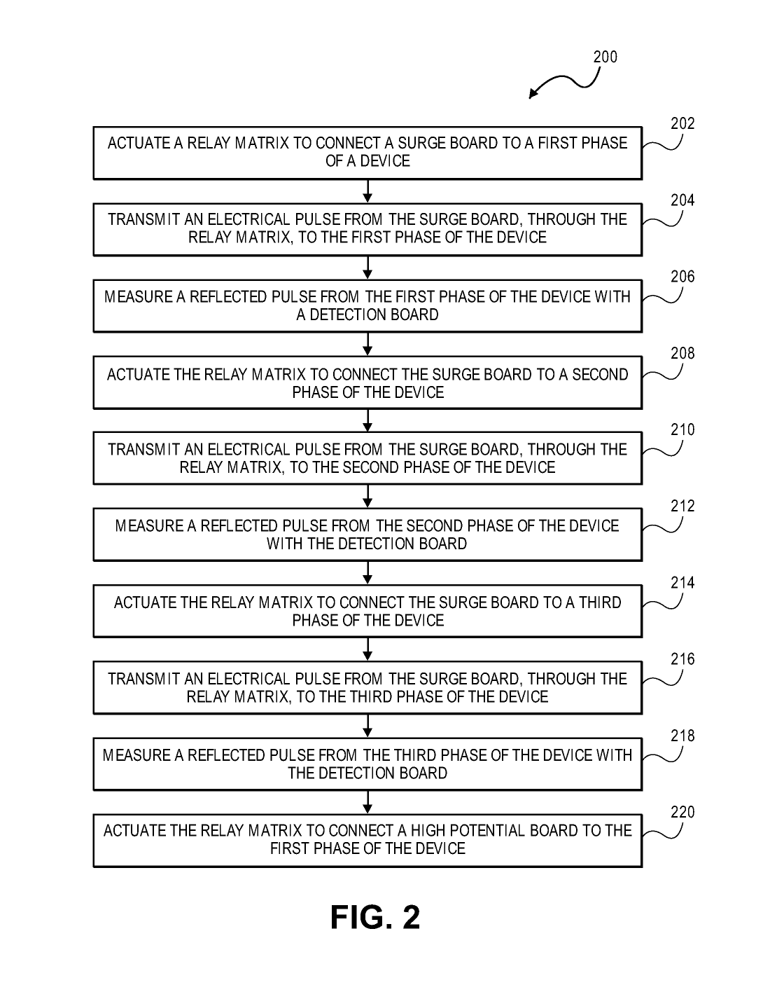

FIG. 2 illustrates a flow chart of a method 200 for detecting a partial discharge, according to an embodiment. The relay matrix 120 is actuated to connect the impulse discharge board 170 to the first connector 112 (e.g., the first phase) of the device 110, as at 202. This includes actuating the first relay 130 into the first position (e.g., connecting the impulse discharge board 170 to the second, third, and fourth relays 140, 150, 160), actuating the second relay 140 into the first position (e.g., connecting the first relay 130 to the first phase of the device 110), and actuating the third and fourth relays 150, 160 into the second position (e.g., connecting the second and third phases of the device 110 to ground 122).

One or more electrical pulses are then transmitted from the impulse discharge board 170, through the relay matrix 120, to the device 110, as at 204. More particularly, the pulses pass through the first relay 130 to the second, third, and fourth relays 140, 150, 160 (e.g., because the first relay 130 is in the first position). The pulses then pass through the second relay 140 to the first connector 112 of the device 110 (e.g., because the second relay 140 is in the first position). No pulses pass through the third and fourth relays 150, 160 to the device 110 (e.g., because the third and fourth relays 150, 160 are in the second position).

After the pulses reach the device 110, the pulses reflect off of the device 110, through the second relay 140, through the first relay 130, and be received by the partial discharge detection board 190. The partial discharge detection board 190 measures the reflected pulses for events that are indicative of partial discharges in the electrical insulation for the first phase of the device 110, as at 206. As used herein, “events” refer to samples which exceed a user-defined magnitude threshold.

The voltage of the pulses from the impulse discharge board 170 is increased until the partial discharge detection board 190 measures a predetermined number of events (e.g., five events) that occur in response to a single reflected pulse. This is the lowest voltage at which a partial discharge is occurring. This voltage is referred to as the “inception voltage.” The voltage of the pulses from the impulse discharge board 170 is then increased until the partial discharge detection board 190 measures a predetermined fraction (e.g., 50%) of the reflected pulses that have the predetermined number of events (e.g., five events). This voltage is referred to as the “repetitive inception voltage.” The voltage of the pulses from the impulse discharge board 170 is then increased until the partial discharge detection board 190 measures 100% of the reflected pulses having the predetermined number of events (e.g., five events).

The voltage of the pulses from the impulse discharge board 170 is then decreased until the partial discharge detection board 190 measures the predetermined fraction (e.g., 50%) of the reflected pulses that have the predetermined number of events (e.g., five events). This voltage is referred to as the “repetitive extinction voltage.” The voltage of the pulses from the impulse discharge board 170 is then decreased until the partial discharge detection board 190 measures zero reflected pulses that have the predetermined number of events (e.g., five events). This voltage is referred to as the “extinction voltage.”

The relay matrix 120 is then actuated to connect the impulse discharge board 170 to the second connector 114 (e.g., the second phase) of the device 110, as at 208. This includes actuating the second relay 140 into the second position (e.g., connecting the first phase of the device 110 to ground) and actuating the third relay 150 into the first position (e.g., connecting the impulse discharge board 170 to the second phases of the device 110). The first relay 130 remains in the first position (e.g., connecting the impulse discharge board 170 to the second, third, and fourth relays 140, 150, 160), and the fourth relay 160 remains in the second position (e.g., connecting the third phase of the device 110 to ground).

Electrical pulses are then transmitted from the impulse discharge board 170 to the device 110, as at 210. More particularly, the pulses pass through the first relay 130 to the second, third, and fourth relays 140, 150, 160 (e.g., because the first relay 130 is in the first position). The pulses then pass through the third relay 150 to the second connector 114 of the device 110 (e.g., because the third relay 150 is in the first position). No pulses pass through the second and fourth relays 140, 160 to the device 110 (e.g., because the second and fourth relays 140, 160 are in the second position).

After the pulses reach the device 110, the pulses reflect off of the device 110, through the third relay 150, through the first relay 130, and be received by the partial discharge detection board 190. The partial discharge detection board 190 measures the reflected pulses for events that are indicative of partial discharges in the electrical insulation of the second phase of the device 110, as at 212. This is performed in the same manner described above (e.g., determining the inception voltage, repetitive inception voltage, repetitive extinction voltage, and extinction voltage for the second phase of the device 110).

The relay matrix 120 is then actuated to connect the impulse discharge board 170 to the third connector 116 (e.g., the third phase) of the device 110, as at 214. This includes actuating the third relay 150 into the second position (e.g., connecting the second phase of the device 110 to ground) and actuating the fourth relay 160 into the first position (e.g., connecting the impulse discharge board 170 to the third phase of the device 110). The first relay 130 remains in the first position (e.g., connecting the impulse discharge board 170 to the second, third, and fourth relays 140, 150, 160), and the second relay 140 remains in the second position (e.g., connecting the first phase of the device 110 to ground).

Electrical pulses are then transmitted from the impulse discharge board 170 to the device 110, as at 216. More particularly, the pulses pass through the first relay 130 to the second, third, and fourth relays 140, 150, 160 (e.g., because the first relay 130 is in the first position). The pulses then pass through the fourth relay 160 to the third connector 116 of the device 110 (e.g., because the fourth relay 160 is in the first position). No pulses pass through the second and third relays 140, 150 to the device 110 (e.g., because the second and third relays 140, 150 are in the second position).

After the pulses reach the device 110, the pulses reflect off of the device 110, through the fourth relay 160, through the first relay 130, and be received by the partial discharge detection board 190. The partial discharge detection board 190 measures the reflected pulses for events that are indicative of partial discharges in the electrical insulation of the third phase of the device 110, as at 218. This is performed in the same manner described above (e.g., determining the inception voltage, repetitive inception voltage, repetitive extinction voltage, and extinction voltage for the third phase of the device 110).

The relay matrix 120 is then actuated to connect the high potential board 180 to the first connector 112 (e.g., the first phase) of the device 110, as at 220. This includes actuating the first relay 130 into the second position (e.g., connecting the high potential board 180 to the second, third, and fourth relays 140, 150, 160), actuating the second relay 140 into the first position (e.g., connecting the high potential board 180 to the first phase of the device 110), and actuating the fourth relay 160 into the second position (e.g., connecting the third phase of the device 110 to ground). The third relay 150 remains in the second position (e.g., connecting the second phase of the device 110 to ground). High potential voltage is then applied to the first phase of the device 110 by the high potential board 180. The relay matrix 120 is then actuated to connect the high potential board 180 to the second connector 114 and subsequently the third connector 116 of the device 110 for additional high potential voltage testing.

In one embodiment, the relays 130, 140, 150, 160 in the relay matrix 120 are actuated between their respective positions manually (e.g., by turning a knob or pushing a button on the relay matrix 120). In another embodiment, a user enters a command into a computer that is connected to the relay matrix 120 each time one or more of the relays 130, 140, 150, 160 is/are to be actuated. For example, the user enters a command into the computer after the inception voltage is determined for the first phase of the device 110 but before the repetitive inception voltage is determined for the first phase of the device 110. The user then enters another command into the computer after the repetitive inception voltage is determined for the first phase of the device 110 but before the repetitive extinction voltage is determined for the first phase of the device 110, and so on. In yet another embodiment, the system 100, including the relay matrix 120, is automated so that the relay matrix 120 automatically actuates the relays 130, 140, 150, 160 as the system 100 performs at least a portion of the method 200. For example, the relay matrix 120 automatically actuates one or more of the relays after the inception voltage is determined for the first phase of the device 110 but before the repetitive inception voltage is determined for the first phase of the device 110.

While the present teachings have been illustrated with respect to one or more implementations, alterations and/or modifications may be made to the illustrated examples without departing from the spirit and scope of the appended claims. In addition, while a particular feature of the present teachings may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” Further, in the discussion and claims herein, the term “about” indicates that the value listed may be somewhat altered, as long as the alteration does not result in nonconformance of the process or structure to the illustrated embodiment. Finally, “exemplary” indicates the description is used as an example, rather than implying that it is an ideal.

Other embodiments of the present teachings will be apparent to those skilled in the art from consideration of the specification and practice of the present teachings disclosed herein. It is intended that the specification and examples be considered as exemplary only, with a true scope and spirit of the present teachings being indicated by the following claims.

What is claimed is:

1. A system for detecting a partial discharge in a device, comprising:
an impulse discharge board;
a relay matrix comprising:
a first relay connected to the impulse discharge board; and
a second relay connected to the first relay, a first phase of the device, and a ground connection of the relay matrix, wherein a first electrical pulse from the impulse discharge board passes through the first relay and the second relay to the first phase of the device when the second relay is in a first position, and wherein the first phase of the device is connected to the ground connection when the second relay is in a second position; and
a partial discharge detection board connected to the impulse discharge board, the first relay, or both, wherein the partial discharge detection board measures reflected electrical pulses from the device.

2. The system of claim 1, wherein the first electrical pulse has a voltage from about 0 V to about 15 kV and a duration less than about 100 nanoseconds.

3. The system of claim 1, wherein the first electrical pulse reflects off of the first phase of the device generating a first reflected electrical pulse, and wherein the reflected electrical pulses comprise the first reflected electrical pulse.

4. The system of claim 1, further comprising a high potential board connected to the first relay, wherein the first relay is connected to the impulse discharge board and disconnected from the high potential board when the first relay is in a first position, and wherein the first relay is connected to the high potential board and disconnected from the impulse discharge board when the first relay is in a second position.

5. The system of claim 4, wherein a second electrical pulse from the high potential board passes through the first relay and the second relay to the first phase of the device when the first relay is in the second position and the second relay is in the first position.

6. The system of claim 5, wherein the second electrical pulse from the high potential board has a voltage from about 0 V to about 15 kV.

7. The system of claim 1, further comprising:
a third relay connected to the first relay, a second phase of the device, and the ground connection, wherein a second electrical pulse from the impulse discharge board passes through the first relay and the third relay to the second phase of the device when the third relay is in a first position, and wherein the second phase of the device is connected to the ground connection when the third relay is in a second position; and
a fourth relay connected to the first relay, a third phase of the device, and the ground connection, wherein a third electrical pulse from the impulse discharge board passes through the first relay and the fourth relay to the third phase of the device when the third relay is in a first position, and wherein the third phase of the device is connected to the ground connection when the third relay is in a second position.

8. The system of claim 7, wherein only one of the second relay, the third relay, and the fourth relay is in the first position at a time.

9. The system of claim 1, wherein the device comprises a ground connection that is connected to the ground connection of the relay matrix.

10. The system of claim 1, wherein the second relay is actuates automatically between the first and second positions.

11. A relay matrix, comprising:
a first relay comprising:
a first connector configured to be connected to a first voltage supply;
a second connector configured to be connected to a second voltage supply;
a third connector; and
a switch configured to connect the first and third connectors of the first relay when the switch is in a first position and to connect the second and third connectors of the first relay when the switch is in a second position; and
a second relay comprising:
a first connector connected to the third connector of the first relay;
a second connector connected to a ground;
a third connector configured to be coupled to a first phase of a device; and
a switch configured to connect the first and third connectors of the second relay when the switch is in a first position and to connect the second and third connectors of the second relay when the switch is in a second position.

12. The relay matrix of claim 11, further comprising:
a third relay comprising:
a first connector connected to the third connector of the first relay;
a second connector connected to the ground;
a third connector configured to be coupled to a second phase of a device; and
a switch configured to connect the first and third connectors of the third relay when the switch is in a first position and to connect the second and third connectors of the third relay when the switch is in a second position; and
a fourth relay comprising:
a first connector connected to the third connector of the first relay;
a second connector connected to the ground;
a third connector configured to be coupled to a third phase of a device; and
a switch configured to connect the first and third connectors of the fourth relay when the switch is in a first position and to connect the second and third connectors of the fourth relay when the switch is in a second position.

13. The relay matrix of claim 11, wherein an electrical pulse from the first voltage supply is configured to pass through the first and second relays to the first phase of the device when the first and second relays are each in the first position.

14. The relay matrix of claim 13, wherein a reflected electrical pulse from the first phase of the device is configured to pass through the first and second relays and to a partial discharge detection board when the first and second relays are each in the first position.

15. The relay matrix of claim 13, wherein the electrical pulse from the first voltage supply is configured to pass to the ground when the first relay is in the first position and the second relay is in the second position.

16. A method for detecting a partial discharge in a device, comprising:
actuating a relay matrix to connect an impulse discharge board to a first phase of a device;
transmitting a first electrical pulse from the impulse discharge board, through the relay matrix, to the first phase of the device, wherein the first electrical pulse reflects off of the device producing a first reflected electrical pulse;
measuring the first reflected electrical pulse with a detection board; and
actuating the relay matrix to connect the impulse discharge board to a second phase of the device.

17. The method of claim 16, further comprising:
transmitting a second electrical pulse from the impulse discharge board, through the relay matrix, to the second phase of the device, wherein the second electrical pulse reflects off of the device producing a second reflected electrical pulse; and
measuring the second reflected electrical pulse with the detection board.

18. The method of claim 16, further comprising:
actuating the relay matrix to disconnect from the impulse discharge board and to connect to a high potential board; and
transmitting a second electrical pulse from the high potential board, through the relay matrix, to the first phase of the device, wherein the second electrical pulse is longer than the first electrical pulse.

19. The method of claim 16, wherein the relay matrix comprises a relay connected to impulse discharge board, the first phase of the device, and a ground, wherein the first electrical pulse from the impulse discharge board passes through the relay to the first phase of the device when the relay is in a first position, and wherein the first phase of the device is connected to the ground when the relay is in a second position.

20. The method of claim 19, wherein the first reflected electrical pulse passes through the relay to the detection board when the relay is in the first position.
